(19) United States
(12) Patent Application Publication
(10) Pub. No.: US 2023/0178360 A1
(43) Pub. Date: Jun. 8, 2023

(54) Device Having Cleaning Bodies

(71) Applicant: Tung An Development Ltd., Hsinchu County (TW)

(72) Inventors: Chih-An Ku, Hsinchu County (TW); Tzu-Yen Chuang, Hsinchu County (TW); Hung-Chieh Chao, Hsinchu County (TW); Fu-Qiang Zhang, Hsinchu County (TW); Ming-Chin Tsai, Hsinchu County (TW)

(21) Appl. No.: 17/542,588

(22) Filed: Dec. 6, 2021

(51) Int. Cl. H01L 21/02; B08B 1/04

(52) U.S. Cl. CPC H01L 21/02043; B08B 1/04

(57) ABSTRACT

A cleaning device comprises a carrier and a cleaning unit. On the surface of the carrier, the cleaning unit comprises cleaning bodies of trapezoidal cylinders with a first surface and two inclined planes. The first surface is parallel to the surface of the carrier. The inclined planes face the circumference of the carrier and are separately located between adjacent two of the cleaning bodies. The first surface has a distance of 6.5 mm±10% to the surface of the carrier. The inclined planes at two sides have an angle of 50°±10% in between. When the cleaning body starts contacting a wafer, one of the inclined planes is deformed as a beginning. Then, gentle area changes is formed from contacting until departing between the cleaning body and the wafer. The wafer is thus stably forced to improve cleaning ability of scrubbing and stabilize surface friction of the wafer.

### TECHNICAL FIELD OF THE INVENTION

The present invention relates to a cleaning device; more particularly, to using flat surface to contact wafer for providing less and stable area change, where cleaning ability of scrubbing is improved and surface friction of wafer is stable.

### DESCRIPTION OF THE RELATED ARTS

Most of the semiconductor cleaning sponges in market are cylindrical cleaning beans as shown in FIG. 14. A single cleaning bean of this traditional sponge does not use the front area to scrub the contacted wafer. Instead, a side of the cleaning bean begins deforming on touching. Take 1 millimeter (mm) of pressing down as an example. The front area of the cleaning bean will pass through the wafer only when the contacting point is about to exceed the rotation center (23 degrees) as shown in FIG. 15.

As shown in FIG. 16, through microscopic analysis, the area change between a single cylindrical cleaning bean and the wafer from the initial contacting of 0.1 degree until passing through the top surface shows a steeper slope. Since the area change is also torque change, the change is steep and unstable from the point of view of torque. It is easier to cause scratches on washing the wafer and make the cleaning ability poor.

For the cylindrical cleaning bean currently in market, its initial contacting with the wafer is always the contact of circular arc surface for cleaning. The disadvantage is that the area change of the cleaning bean from contacting to departing the wafer is relatively steep. More area changes are formed to make the wafer unstably forced. In turn, the cleaning ability of scrubbing and the stability of the surface friction of the wafer are reduced.

Hence, the prior art does not fulfill all users' requests on actual use.

### SUMMARY OF THE INVENTION

The main purpose of the present invention is to use flat surface to contact wafer for providing less and stable area change while the cleaning ability of scrubbing is improved and the surface friction of the wafer is stabled.

To achieve the above purpose, the present invention is a cleaning device, comprising a carrier and a cleaning unit, where the carrier has a cylindrical shape; a sleeve unit is set in center of the carrier; the sleeve unit is assembled with an actuating device; the cleaning unit comprises a plurality of cleaning bodies arranged on a surface of the carrier; the cleaning bodies are trapezoidal cylinders; each of the cleaning bodies has a first surface and two inclined planes; the first surface is parallel to a surface of the carrier; the two inclined planes are faced toward circumference of the carrier and separately located between adjacent two of the cleaning bodies; the first surface of the cleaning body has a distance of 6.5 millimeters (mm) to the surface of the carrier with 10 percent (%) tolerance (±10%); the two inclined planes at two sides have an angle of 50 degrees±10% in between; as one of the cleaning bodies starts contacting a wafer, one of the inclined planes at a side is deformed as a beginning; as follows, a trend of gentle changes in area is formed from initial contacting until final departing between each of the cleaning bodies and the wafer; and the wafer is thus stably forced with cleaning ability of scrubbing and surface friction of the wafer both improved. Accordingly, a novel cleaning device is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the sectional view showing the preferred embodiment according to the present invention;

FIG. 2 is the perspective view showing the cleaning body;

FIG. 3 is the structural view showing the cleaning body;

FIG. 4 is the view showing the rotation of the cleaning body;

FIG. 5 is the view showing the change of contacting area during the rotation of the cleaning body;

FIG. 6 is the comparison view showing the change of contacting area;

FIG. 7 is the comparison view showing the normalized contacting area over the contacting angle;

FIG. 8 is the comparison view showing the normalized contacting area over the normalized contacting angle;

FIG. 9 is the comparison view showing the increase of contacting area over the normalized contacting angle;

FIG. 10 is the comparison view showing the contacting angle over the normalized contacting area;

FIG. 11 is the comparison view showing the normalized contacting angle over the normalized contacting area;

FIG. 12 is the comparison view showing the contacting angle over the contacting area;

FIG. 13 is the comparison view showing the normalized contacting angle over the contacting area;

FIG. 14 is the view of the prior art;

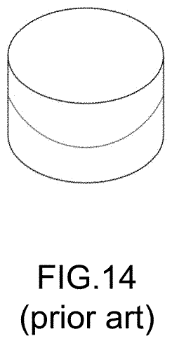

FIG. 15 is the view of the rotation of the cleaning body of the prior art; and

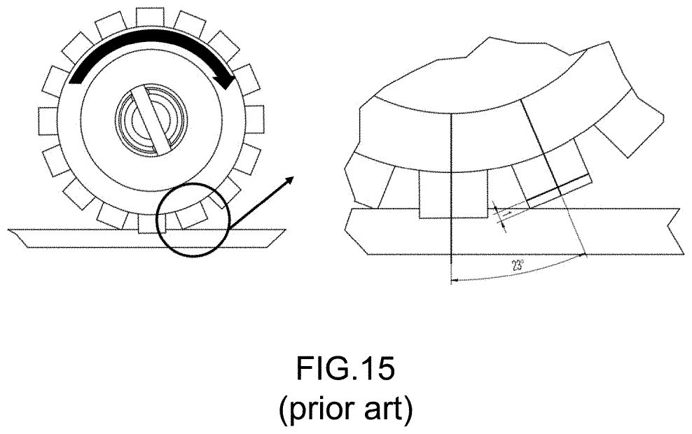

FIG. 16 is the view of the change of contacting area during the rotation of the cleaning body of the prior art.

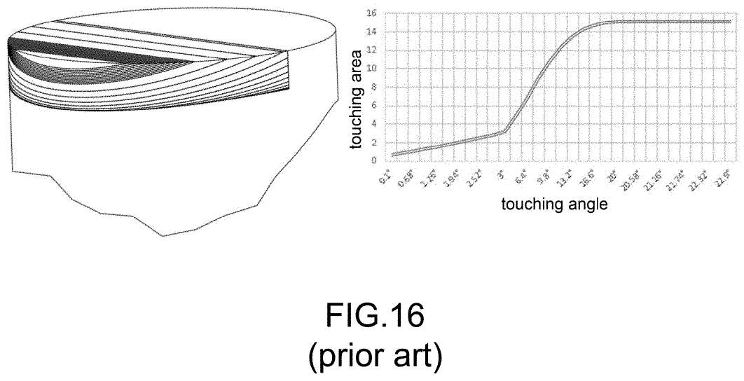

### DESCRIPTION OF THE PREFERRED EMBODIMENT

The following description of the preferred embodiment is provided to understand the features and the structures of the present invention.

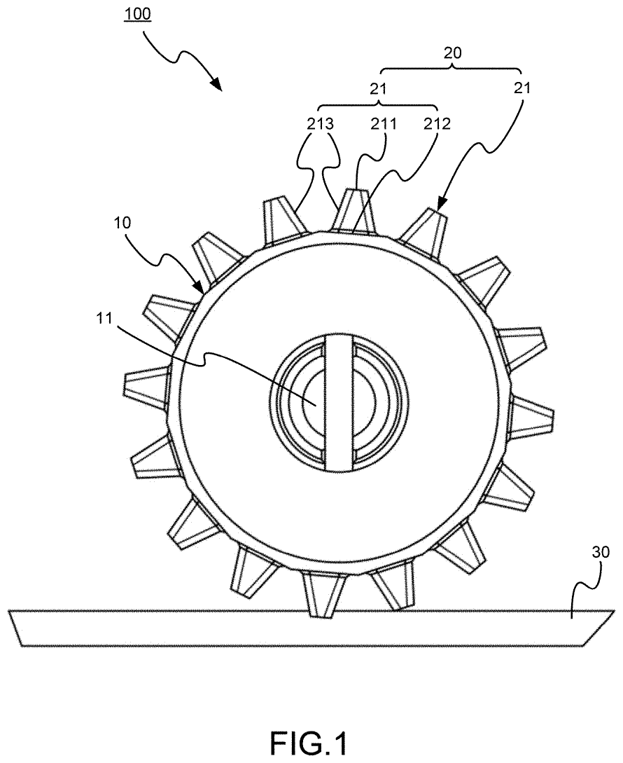

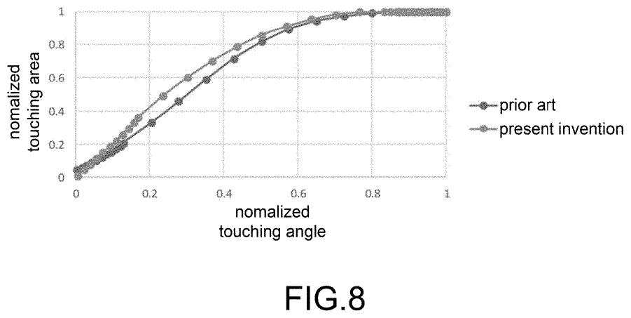

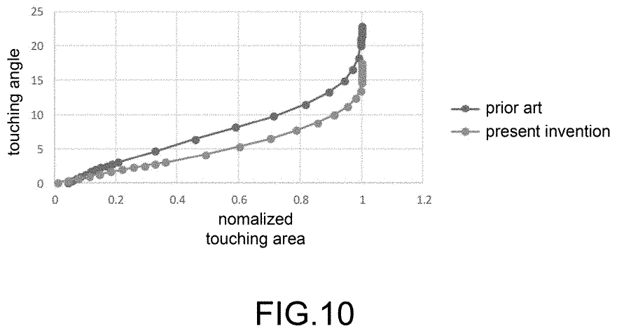

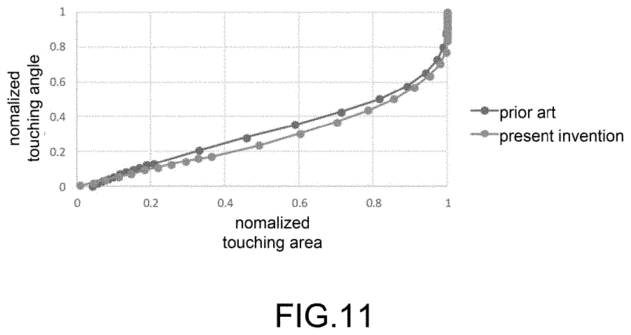

Please refer to FIG. 1 to FIG. 13, which are a sectional view showing a preferred embodiment according to the present invention; a perspective view showing a cleaning body; a structural view showing the cleaning body; a view showing rotation of the cleaning body; a view showing change of contacting area during rotation of the cleaning body; a comparison view showing the change of contacting area; a comparison view showing normalized contacting area over contacting angle; a comparison view showing the normalized contacting area over normalized contacting angle; a comparison view showing increase of contacting area over the normalized contacting angle; a comparison view showing contacting angle over the normalized contacting area; a comparison view showing normalized contacting angle over the normalized contacting area; a comparison view showing contacting angle over contacting area; and a comparison view showing normalized contacting angle over the contacting area. As shown in the figures, the present invention is a cleaning device 100, comprising a carrier 10 and a cleaning unit 20, where the carrier 10 and the cleaning unit 20 are formed integrally by foaming with a composite material, a sponge, polyurethane (PU), polyvinyl alcohol (PVA), or a polymer material, etc.

The carrier 10 has a cylindrical shape, where a sleeve unit 11 is set in center to be assembled with an actuating device (not shown in the figure).

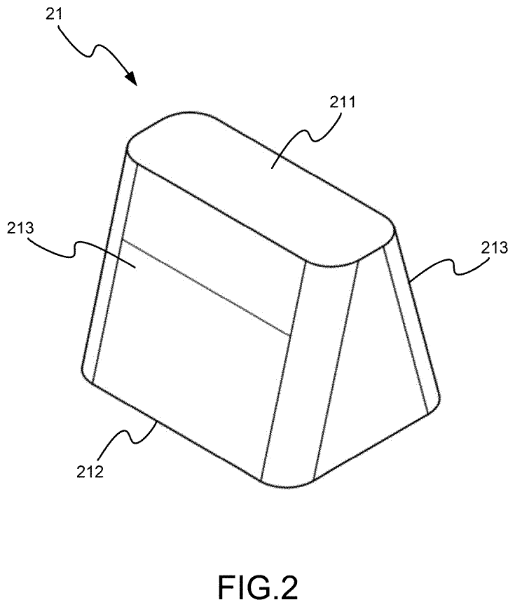

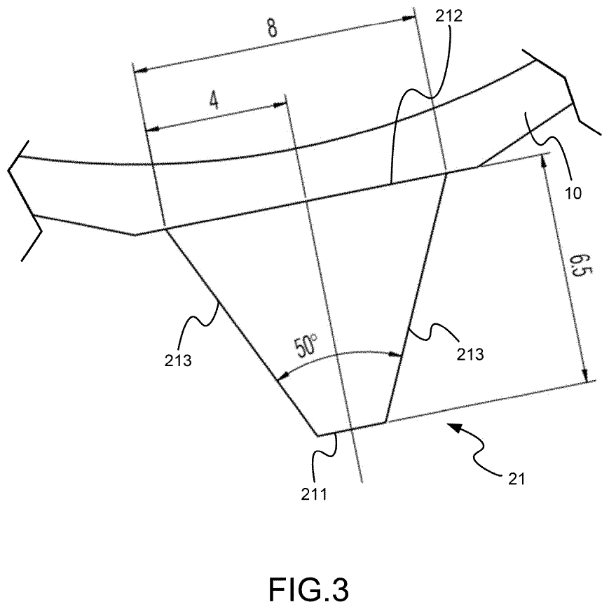

The cleaning unit 20 is set on an outer edge of the carrier 10, where the cleaning unit 20 comprises a plurality of cleaning bodies 21 arranged on a surface of the carrier 10. The cleaning bodies 21 are trapezoidal cylinders (e.g., isosceles trapezoidal cylinders, as shown in FIG. 2). Each of the trapezoidal cylinders comprises a first surface 211 being parallel to a surface of the carrier 10; a second surface 212 connecting the surface of the carrier 10; and two inclined planes 213 facing circumference of the carrier 10 and being separately located between adjacent two of the cleaning bodies 21. As shown in FIG. 2 and FIG. 3, the first surface 211 of each of the cleaning bodies 21 has an outer shape of a rectangle with corners rounded and has a distance of 6.5 millimeters (mm) to the surface of the carrier 10; the second surface 212 has a center point distancing 4 mm to each position that each of the inclined planes 213 at two sides is in contact with; and the two inclined planes 213 at two sides have an angle of 50 degrees (°) in between. Thus, a novel cleaning device 100 is obtained.

In a state-of-use, the first surface 211 of each of the cleaning bodies 21 has an arc concaved at center; and the arc has a curvature of 70 percent (%) to 99%.

In a state-of-use, a gap is formed between each adjacent two of the cleaning bodies 21, where the gaps are formed with equal spacing, unequal spacing, or a combination of the above two spacing. Furthermore, the cleaning bodies 21 are set on the surface of the carrier 10 in a honeycomb arrangement, an equidistant arrangement, a spiral arrangement, or a two-way spiral arrangement.

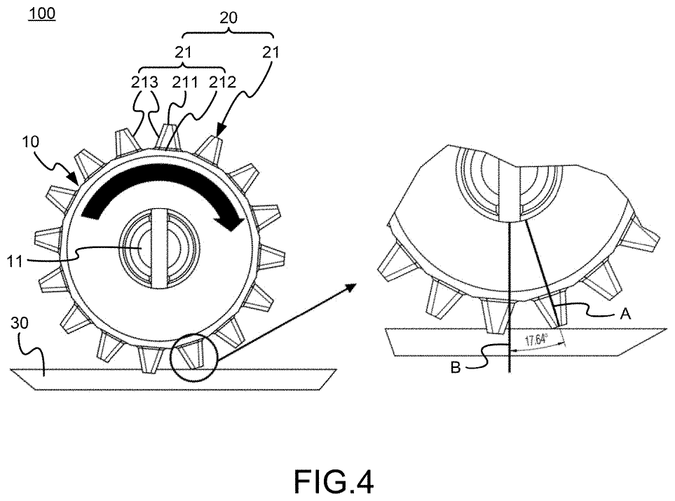

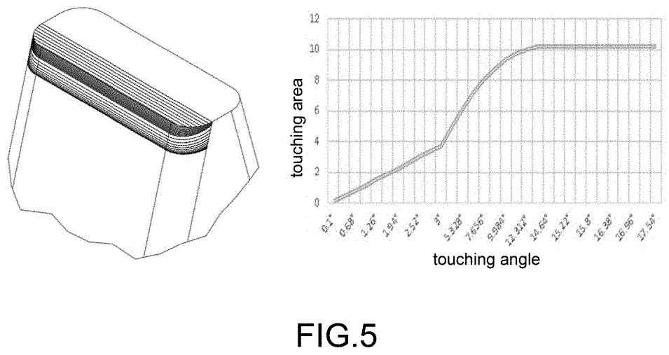

On using the present invention, at least one carrier 10 is assembled with a related actuating device (not shown in the figure) by using the sleeve unit 11, so that the actuating device carries the carrier 1 to roll and move according to a requested cleaning condition and position for making the cleaning bodies 21 of the cleaning unit 2 on the outer edge of the carrier 10 in touch with the surface of a related precision electronic device for cleaning. In a state-of-use, during a horizontal washing, the precision electronic device (e.g., the wafer 30) rotates clockwise or counterclockwise in an original position with the cylindrical carrier 10 carrying the cleaning unit 2 to rotate as well, where FIG. 4 shows a clockwise rotation. When one of the cleaning bodies 21 starts contacting the wafer 30, the cleaning body 21 does not contact and wash the wafer 30 with the first surface 211 but rather by deforming one of the inclined planes 213 at a side as a beginning. Assuming that a pressing down of 1 mm happens. Then, after the carrier 10 carries the cleaning unit 20 to rotate and contact and pass over a rotation angle where a straight line 42 is defined by connecting the center of the carrier 10 and a position of the wafer 30 contacting the cleaning device 100 to form the rotation angle of 17.64° between the straight line 42 and a central extension axis of the cleaning body 21 adjacent thereto, the cleaning body 21 passes through the wafer 30 with the area of the first surface 211 as shown in FIG. 5. As follows, a trend of gentle changes in area is formed from initial contacting until final departing between the cleaning body 21 and the wafer 30; and the wafer 30 is thus stably forced with cleaning ability of scrubbing and stability of surface friction both improved.

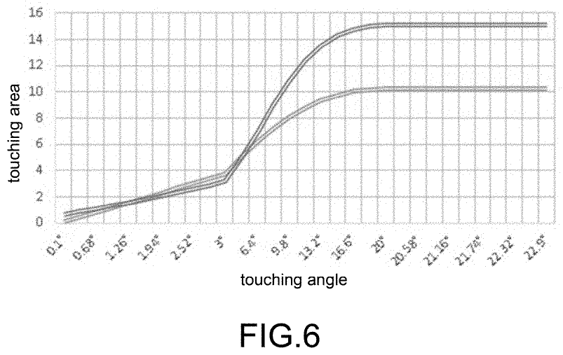

A traditional cylindrical cleaning body is compared with the trapezoidal cylindrical cleaning body according to the present invention. As shown in FIG. 6, the area change of 30 operating angles are shown, where, from 0° to 3° in front, it seems that the traditional cylindrical cleaning body has a calmer change (the dotted line on white background); and, after the middle section, the trapezoidal cylindrical cleaning body obtains a calmer change (the dotted line on black background). It is found that, as compared with the traditional cylindrical cleaning body, the cleaning body with a trapezoidal cylindrical shape according to the present invention has slow change in contacting area from touching to separating while the cylindrical cleaning body has steeper slope of change. The changes are slower and more stable from the point of view of torque without causing scratches on washing the wafer 30 as providing better cleaning ability.

Accordingly, the larger the angle between the inclined planes of the cleaning body on two sides, the smoother is the response of the torque. Therefore, the cleaning device with 16 rows of cleaning bodies 21 reaches a maximum performance at 50° according to the present invention.

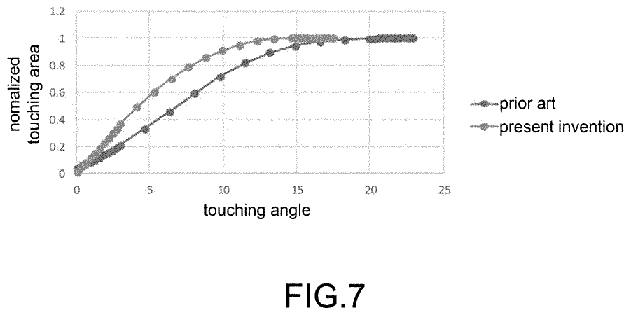

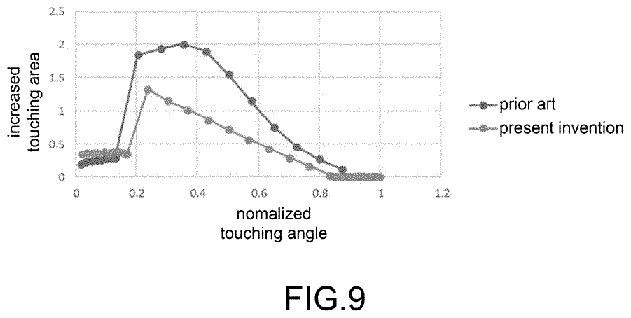

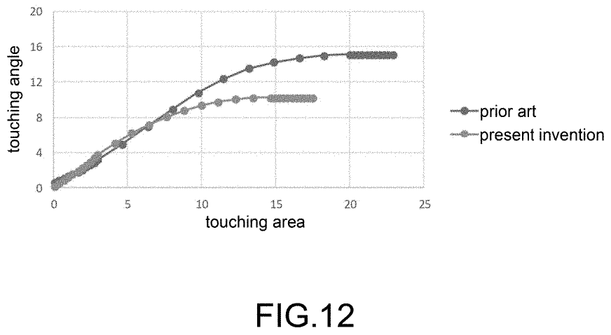

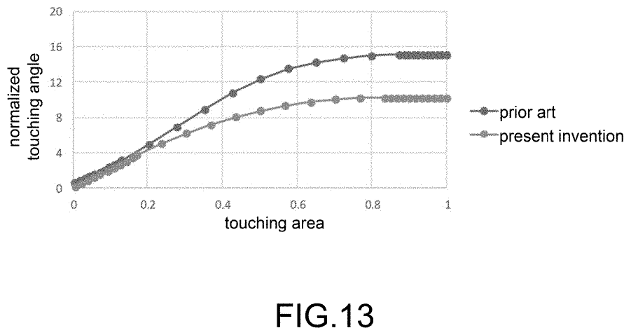

A series of comparison between the trapezoidal cylindrical cleaning body of the present invention and the traditional cylindrical cleaning body are shown in FIG. 7˜FIG. 13. Therein, as comparing the traditional cylindrical cleaning body with the trapezoidal cylindrical cleaning body of the present invention at the same length (the diameter length of the traditional cylindrical cleaning body and that of the trapezoidal cylindrical cleaning body), the total change in area of the trapezoidal cylindrical cleaning body is smaller than that of the traditional cylindrical cleaning body for providing a more stable brushing speed change (or torque change) as shown in FIG. 12. Furthermore, in terms of the change in area for each angle, the maximum change of the trapezoidal cylindrical cleaning body of the present invention is obviously smaller than that of the traditional cylindrical cleaning body for providing a more stable brushing speed change (or torque change) as shown in FIG. 9.

Thus, the present invention is characterized in using the contacting area for washing in the beginning, which has an advantage that the area change of the cleaning body is relatively smooth from contacting the wafer until leaving it as the force on the wafer is also relatively stable. According to the above data, it is proved that, as compared to the prior art, the present invention uses flat surface to contact wafer for providing less and stable area change while the cleaning ability of scrubbing is further improved and the surface friction of the wafer is stabler.

To sum up, the present invention is a cleaning device, where flat surface is used to contact wafer for providing less and stable area change while the cleaning ability of scrubbing is further improved and the surface friction of the wafer is stabler.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A cleaning device, comprising
a carrier,
wherein said carrier has a cylindrical shape; a sleeve unit is obtained in center of said carrier; and said sleeve unit is assembled with an actuating device; and
a cleaning unit,
wherein said cleaning unit comprises a plurality of cleaning bodies arranged on a surface of said carrier; said cleaning bodies are trapezoidal cylinders; each of the cleaning bodies has a first surface and two inclined planes; said first surface is parallel to a surface of said carrier; said two inclined planes are faced toward circumference of said carrier and separately located between adjacent two of said cleaning bodies; said first surface of said cleaning body has a distance of 6.5 millimeters (mm) to said surface of said carrier with 10 percent (%) tolerance (±10%); and said two inclined planes at two sides have an angle of 50 degrees±10% in between,
wherein, as any one of said cleaning bodies starts contacting a wafer, one of said inclined planes at a side is deformed as a beginning; as follows, a trend of gentle changes in area is obtained from initial contacting until final departing between said one of said cleaning bodies and said wafer; and said wafer is thus stably forced with cleaning ability of scrubbing and surface friction of said wafer.

2. The cleaning device according to claim 1,
wherein said cleaning bodies are isosceles trapezoidal cylinders.

3. The cleaning device according to claim 1,
wherein said first surface of one of said cleaning bodies has an arc concaved at center; and said arc has a curvature of 70%˜99%.

4. The cleaning device according to claim 1,
wherein each adjacent two of said cleaning bodies has a gap in between.

5. The cleaning device according to claim 4,
wherein said gaps between said cleaning bodies are obtained with spacing selected from a group consisting of equal spacing, unequal spacing, and a combination of the above two spacing.

6. The cleaning device according to claim 1,
wherein said cleaning bodies are placed in an arrangement selected from a group consisting of a honeycomb arrangement, an equidistant arrangement, a spiral arrangement, and a two-way spiral arrangement.

7. The cleaning device according to claim 1,
wherein said carrier and said cleaning unit are formed into one by foaming a soft foam.

8. The cleaning device according to claim 1,
wherein a straight line is defined by connecting the center of said carrier and a position of said wafer contacting the cleaning device to obtain a rotation angle between said straight line and a central extension axis of one of said cleaning bodies adjacent thereto; and, as said carrier carries said cleaning unit to rotate beyond said rotation angle to press down and deform one of said inclined planes at a side of said one of said cleaning bodies on contacting said wafer, said one of said cleaning bodies passes through said wafer with the area of said first surface.

9. The cleaning device according to claim 1,
wherein said first surface of one of said cleaning bodies has an outer shape of a rectangle with corners rounded.

10. The cleaning device according to claim 1,
wherein each of said cleaning bodies further has a second surface connecting said surface of said carrier; and said second surface has a center point distancing 4 mm to each position that each of said inclined planes at two sides is in contact with.
